(19) United States
(12) Patent Application Publication
(10) Pub. No.: US 2012/0081845 A1
(43) Pub. Date: Apr. 5, 2012

(54) INFORMATION PROCESSING APPARATUS

(75) Inventor: Shinsuke YATO, Akishima-shi (JP)

(73) Assignee: KABUSHIKI KAISHA TOSHIBA, Tokyo (JP)

(21) Appl. No.: 13/232,895

(22) Filed: Sep. 14, 2011

(30) Foreign Application Priority Data
Sep. 30, 2010 (JP) P2010-223184

(51) Int. Cl. H05K 7/00

(52) U.S. Cl. 361/679.01

(57) ABSTRACT

According to one embodiment, an information processing apparatus includes a display module, a first button, a second button, a third button, and a controller. The display module is configured to display an image in a first or second orientation. The first and second buttons are disposed substantially symmetrically with respect to a first axis. The third button is disposed substantially symmetrically to the second button with respect to a second axis intersecting the first axis at a substantially right angle. The controller is configured to assign a first function and a second function to the first button and the second button, respectively, when the display module displays the image in the first orientation, and to assign the first function and the second function to the second button and the third button, respectively, when the display module displays the image in the second orientation.

### CROSS REFERENCE TO RELATED APPLICATION(S)

This application is based upon and claims the benefit of priority from Japanese Patent Application No. 2010-223184 filed on Sep. 30, 2010, the entire contents of which are incorporated herein by reference.

### FIELD

Embodiments described herein relate generally to an information processing apparatus.

### BACKGROUND

In recent years, information processing apparatuses have been spreading that can be used both in the vertical direction (vertical type) and in the horizontal direction (horizontal type) with respect to the ground.

However, if the user interface is different between when an information processing apparatus is used in the vertical direction and when it is used in the horizontal direction, this may make the apparatus awkward to operate.

### BRIEF DESCRIPTION OF THE SEVERAL VIEWS OF THE DRAWINGS

A general configuration that implements the various features of the invention will be described with reference to the drawings. The drawings and the associated descriptions are provided to illustrate embodiments of the invention and not to limit the scope of the invention.

FIG. 1 is an exemplary perspective view showing an outer appearance of an information processing apparatus according to a first embodiment;

FIGS. 2A and 2B are exemplary front views showing the outer appearance of the information processing apparatus according to the first embodiment;

FIG. 3 is an exemplary functional block diagram showing a structure of the information processing apparatus according to the first embodiment;

FIG. 4 is an exemplary view showing a button function assignment of the information processing apparatus according to the first embodiment;

FIG. 5 is an exemplary view showing a LED lighting color assignment of the information processing apparatus according to the first embodiment;

FIG. 6 is an exemplary flow chart showing a processing based on a holding condition of the information processing apparatus according to the first embodiment;

FIG. 7 is an exemplary flow chart showing the processing based on the holding condition of the information processing apparatus according to the first embodiment;

FIG. 8 is an exemplary perspective view showing a modified example of an outer appearance of an information processing apparatus according to the first embodiment;

FIGS. 9A and 9B are exemplary front views showing the modified example of the outer appearance of the information processing apparatus according to the first embodiment;

FIGS. 10A to 10D are exemplary front views showing an outer appearance of the information processing apparatus according to the second embodiment;

FIG. 11 is an exemplary view showing a button function assignment of the information processing apparatus according to the second embodiment; and

FIG. 12 is an exemplary view showing a LED lighting color assignment of the information processing apparatus according to the second embodiment.

### DETAILED DESCRIPTION

In general, according to one embodiment, an information processing apparatus includes a display module, a first button and a second button, a third button and a controller. The display module is configured to display an image in a first orientation or in a second orientation. The first button and the second button are disposed substantially symmetrically with respect to a first axis passing in a center of the display module. The third button is disposed substantially symmetrically to the second button with respect to a second axis intersecting the first axis at a substantially right angle in the center of the display module. The controller is configured to assign a first function and a second function to the first button and the second button, respectively, when the display module displays the image in the first orientation, and to assign the first function and the second function to the second button and the third button, respectively, when the display module displays the image in the second orientation.

Hereinafter, exemplary embodiments will be described with reference to the drawings.

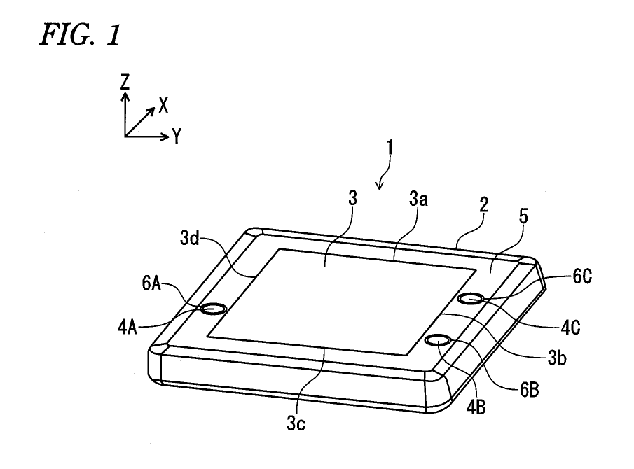

An outer appearance of an information processing apparatus according to a first embodiment will be described with reference to FIG. 1. FIG. 1 is a perspective view showing the outer appearance of the information processing apparatus 1 according to the first embodiment.

As shown in FIG. 1, the information processing apparatus 1 has a rectangular flat shape. In the first embodiment, for convenience of explanation, directions (the x direction, the y direction and the z direction) are defined. The x direction and the y direction are directions substantially along the surface of the information processing apparatus 1. The x direction is the direction of the depth of the information processing apparatus 1 (the direction of the short side of a surface 5). The y direction is the direction of the width of the information processing apparatus 1 (the direction of the long side of the surface 5). The z direction is a direction vertical to the surface 5 of the information processing apparatus 1 (the direction of the thickness of the information processing apparatus). The x direction, the y direction and the z direction are orthogonal to one another.

As shown in FIG. 1, the information processing apparatus 1 is provided with a display 3 such as an LCD as a display module and operation buttons 4A, 4B and 4C so as to be exposed at the surface 5 of a housing 2. The user performs various operations by operating operation buttons 4A, 4B and 4C.

The four sides forming the outer shape of the display 3 are defined as shown in FIG. 1. The side parallel to the y axis on the side of the button 4C is defined as a long side 3a, the side parallel to the x direction on the side of the buttons 4B and 4C is defined as a short side 3b, the side parallel to the y axis on the side of the buttons 4A and 4B is defined as a long side 3c, and the side parallel to the x direction on the side of the button 4A is defined as a short side 3d.

The button 4A is disposed substantially symmetrically to the button 4B with respect to the axis 1. The button 4c is disposed substantially symmetrically to the button 4B with respect to the axis 2. The axis 1 and the axis 2 are virtual lines that vertically intersect substantially at the center of the display 3. The axis 1 extends in the x direction, whereas the axis 2 extends in the y direction.

Around the operation buttons 4A, 4B and 4C, LEDs 6A, 6B and 6C for indication are disposed. The LEDs 6A, 6B and 6C are capable of lighting in a plurality of colors, and indicate the functions of the corresponding operation buttons 4A, 4B and 4C by the colors in which they light.

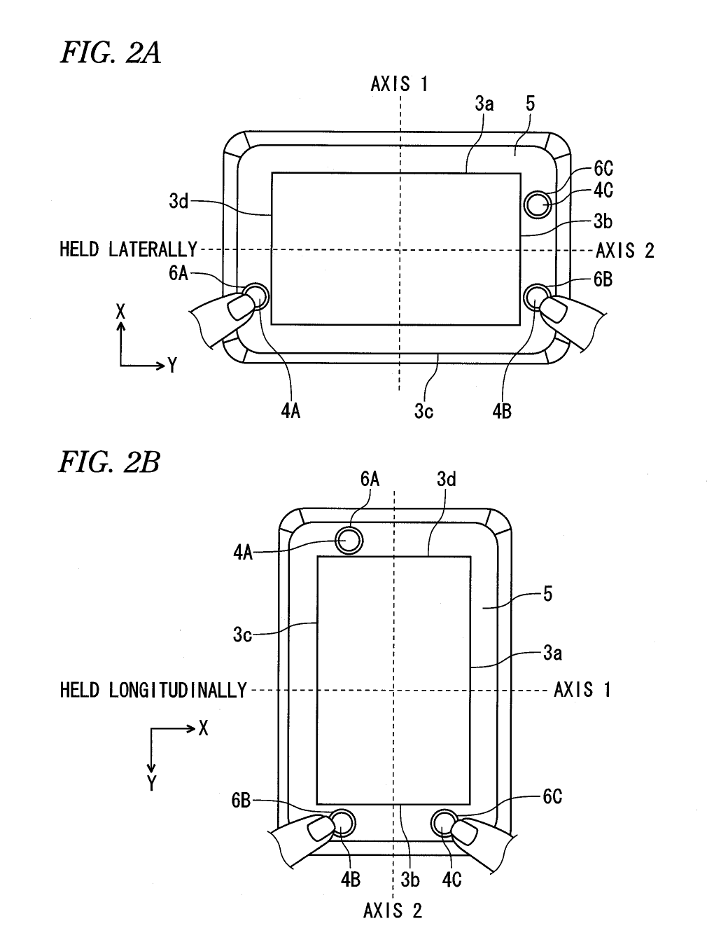

As shown in FIGS. 2A and 2B, the user can hold the information processing apparatus 1 laterally (FIG. 2A) and longitudinally (FIG. 2B). The display direction of the image displayed on the display 3 of the information processing apparatus 1 is different between when the apparatus 1 is held longitudinally and when it is held laterally. When the information processing apparatus 1 is held laterally (the direction of the long side of the surface 5 [y direction] is substantially parallel to the ground) as shown in FIG. 2A, the image is displayed so that the long side 3c of the display 3 is close to the user. When the information processing apparatus 1 is held longitudinally (the direction of the short side of the surface 5 [x direction] is substantially parallel to the ground) as shown in FIG. 2B, the image is displayed so that the short side 3b of the display 3 is close to the user.

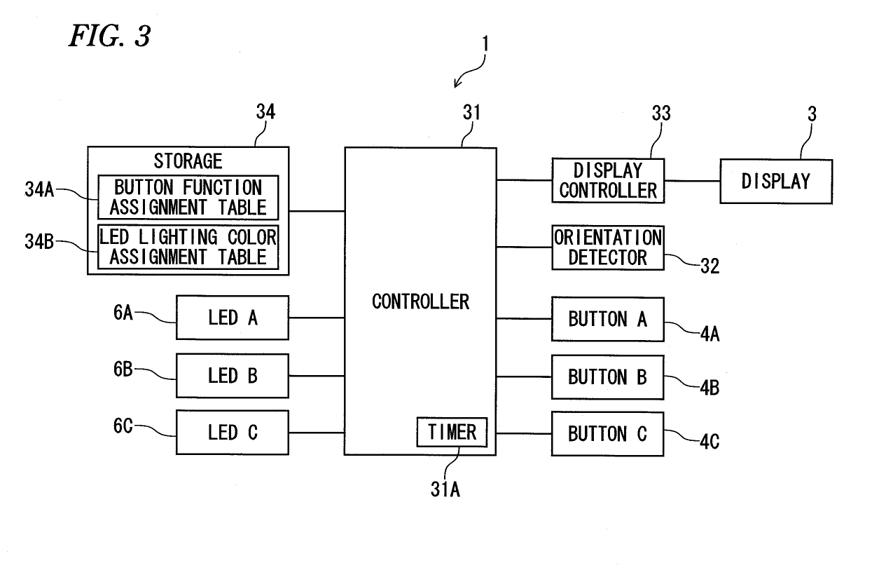

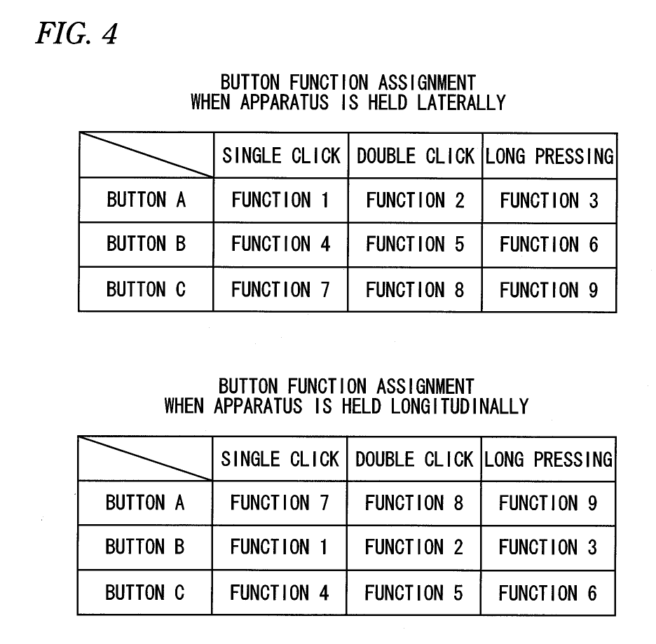

In the first embodiment, the functions assigned to a first, second and third buttons are different between when the information processing apparatus 1 is held laterally and when it is held longitudinally. More specifically, the functions assigned to the operation buttons 4A, 4B and 4C when the apparatus 1 is held laterally (FIG. 2A) are assigned to the operation buttons 4B, 4C and 4A when the apparatus 1 is held longitudinally (FIG. 2B). By the assigned functions being different between when the apparatus 1 is held laterally and when it is held longitudinally, the colors of the LEDs 6A, 6B and 6C are changed. More specifically, the colors of the LEDs 6A, 6B and 6C when the apparatus 1 is held laterally (FIG. 2A) are the same as those of the LEDs 6B, 6C and 6A when the apparatus 1 is held longitudinally (FIG. 2B). Details of the assignment of the functions and the LED colors will be described later with reference to FIGS. 3 and 4.

Next, the structure of the information processing apparatus 1 will be described with reference to FIG. 3. FIG. 3 is a functional block diagram showing an example of the structure of the information processing apparatus 1.

A controller 31 performs control of components in the information processing apparatus 1. For example, according to the holding condition (whether held longitudinally or laterally) of the information processing apparatus detected by an orientation detector 32, the controller 31 changes the functions assigned to the button A 4A, the button B 4B and the button C 4C and the colors in which the LEDs A 6A, the LED B 6B and the LED C 6C light. The controller 31 also changes the orientation of the image displayed on the display 3 as shown in FIGS. 2A and 2B.

The controller 31 includes a timer 31A. The timer 31A measures, for example, the pressing time and the pressing interval of the buttons A, B and C. The controller 31 determines whether the inputted user operation is a single click, a double click or a long pressing according to the measured time, and executes the assigned operation according to the kind of the operation.

The orientation detector 32 is, for example, a gyro sensor or an acceleration sensor, and detects the orientation of the information processing apparatus 1 with respect to the ground to thereby detect whether the apparatus 1 is held longitudinally or laterally. Further, the orientation detector 32 outputs the detected orientation to the controller 31, and the controller 31 performs various controls according to the holding direction.

A display controller 33 displays an image on the display 3 in response to an instruction from the controller 31. The image displayed on the display 3 differs according to whether the information processing apparatus 1 is held longitudinally or laterally as mentioned above.

A storage 34 is, for example, a nonvolatile memory such as a flash ROM or an HDD (hard disk drive), and stores a button function assignment table 34A, an LED lighting color assignment table 34B and the like. Referring to the button function assignment table 34A and the LED lighting color assignment table 34B, the controller 31 performs function assignment to the buttons and lighting color assignment to the LEDs according to the orientation detected by the orientation detector 32.

An example of the button function assignment table 34A is shown in FIG. 4. As shown in FIG. 4, in the button function assignment table 34A, a plurality of functions are defined that are assigned to the button A, the button B and the button C when the information processing apparatus 1 is held laterally and when it is held longitudinally. The user can perform three kinds of operations, a single click, a double click and a long pressing on the buttons, and a different function is assigned to each.

More specifically, when the information processing apparatus 1 is held laterally, to the button A, a function 1 is assigned when it is single clicked, a function 2 is assigned when it is double clicked, and a function 3 is assigned when it is long pressed. To the button B, a function 4 is assigned when it is single clicked, a function 5 is assigned when it is double clicked, and a function 6 is assigned when it is long pressed. To the button C, a function 7 is assigned when it is single clicked, a function 8 is assigned when it is double clicked, and a function 9 is assigned when it is long pressed.

When the information processing apparatus 1 is held longitudinally, to the button A, the function 7 is assigned when it is single clicked, the function 8 is assigned when it is double clicked, and the function 9 is assigned when it is long pressed. These functions are assigned to the button C when the information processing apparatus 1 is held laterally. To the button B, the function 1 is assigned when it is single clicked, the function 2 is assigned when it is double clicked, and the function 3 is assigned when it is long pressed. These functions are assigned to the button A when the information processing apparatus 1 is held laterally. To the button C, the function 4 is assigned when it is single clicked, the function 5 is assigned when it is double clicked, and the function 6 is assigned when it is long pressed. These functions are assigned to the button B when the information processing apparatus 1 is held longitudinally.

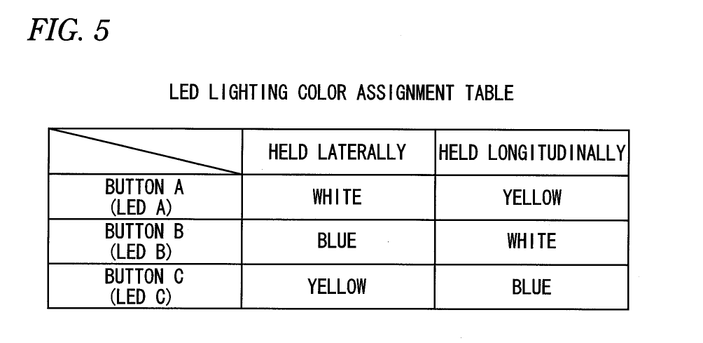

Next, the LED lighting color assignment table 34B will be described with reference to FIG. 5. FIG. 5 is a view showing an example of the LED lighting color assignment table 34B. As shown in FIG. 5, in the LED lighting color assignment table 34B, the lighting colors in which the LED A (the LED corresponding to the button A), the LED B (the LED corresponding to the button B) and the LED C (the LED corresponding to the button C) light are assigned according to whether the information processing apparatus 1 is held longitudinally or laterally as in the button function assignment table 34A.

More specifically, when the information processing apparatus 1 is held laterally, white, blue and yellow are assigned to the LED A, the LED B and the LED C, respectively. When the information processing apparatus 1 is held longitudinally, yellow, white and blue are assigned to the LED A, the LED B and the LED C, respectively. These lighting colors correspond to the functions described with reference to the button function assignments described by using FIG. 4. The lighting colors assigned to the LED A, the LED B and the LED C, respectively, when the information processing apparatus 1 is held laterally are the same as those assigned to the LED B, the LED C and the LED A, respectively, when the apparatus 1 is held longitudinally.

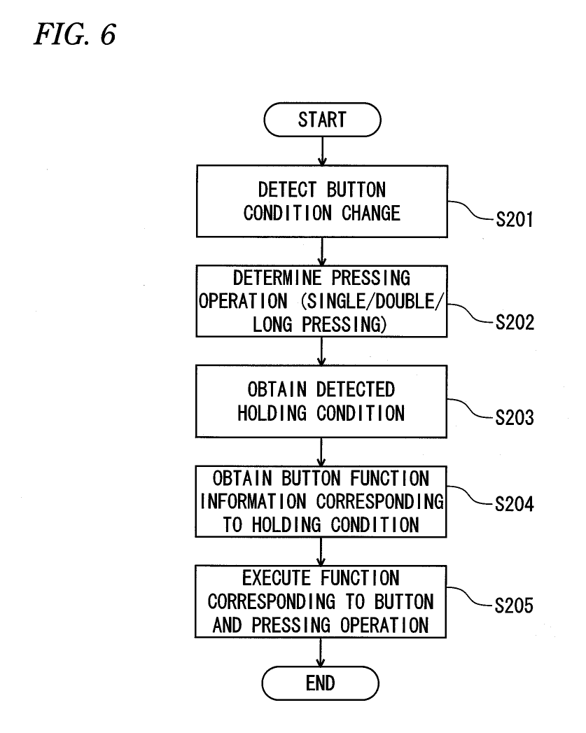

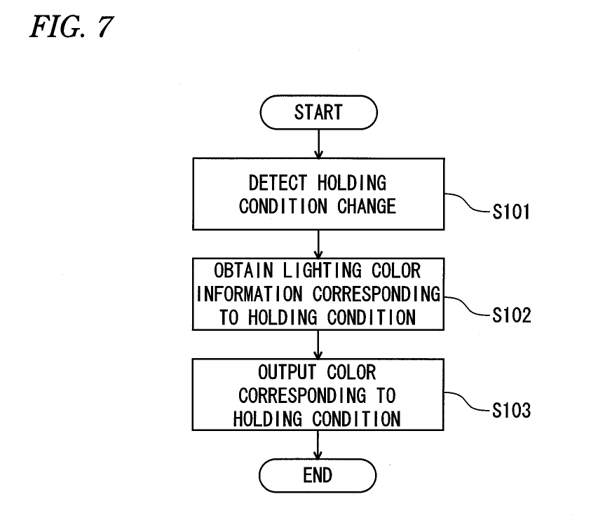

Next, the processing of function and LED lighting color assignments with a change of the holding condition will be described with reference to FIGS. 6 and 7. First, the processing performed when a button is pressed will be described with reference to FIG. 6.

When the user presses a button (any of the button A, the button B and the button C) and the controller 31 detects a signal thereof (S201), the controller 31 determines the kind of the operation (pressing operation) (S202). The operation kind determination is, more specifically, a determination as to whether the user's operation input to the button is a single click, a double click or a long pressing.

Further, the controller 31 obtains the holding condition (held longitudinally or laterally) represented by the orientation detection signal having been detected by the orientation detector 32 (S203). Then, based on the obtained holding condition and the pressing operation, the controller 31 refers to the button function assignment table 34A, and obtains the function to be assigned (button function information) corresponding to the operation and the holding condition (S204). Then, the controller 31 executes the function corresponding to the obtained button function information (S205).

Next, the LED lighting color assignment processing will be described with reference to FIG. 7.

When the user changes the holding condition of the information processing apparatus 1 and the orientation detector 32 detects the change (S101), the controller 31 obtains the LED lighting color to be assigned (light color information) corresponding to the detected holding condition (S102). Then, the controller 31 changes the colors of the LED A, the LED B and the LED C according to the obtained lighting color information (S103).

As described above, according to the first embodiment, the image display orientation and the functions assigned to the button 4A, the button 4B and the button 4C are changed according to the change of the holding condition, so that user operation convenience improves. In particular, the information processing apparatus 1 has a substantially rectangular shape, the display is disposed substantially in the center, and the buttons 4A and 4B and the buttons 4B and 4C are disposed in positions substantially symmetrical with respect to the display, so that changes in operational feeling in response to the holding condition are extremely small.

Moreover, since the colors of the LED A, the LED B and the LED C are changed according to the holding condition, it is enabled to inform the user that the functions assigned to the buttons are changed, which facilitates user operation.

Further, since the functions corresponding to all the operation of a single click, a double click and a long pressing are changed according to the holding condition, user convenience can be further improved.

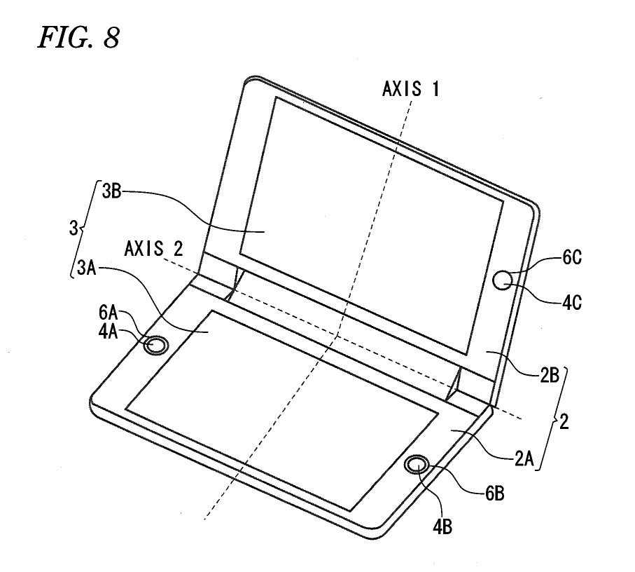

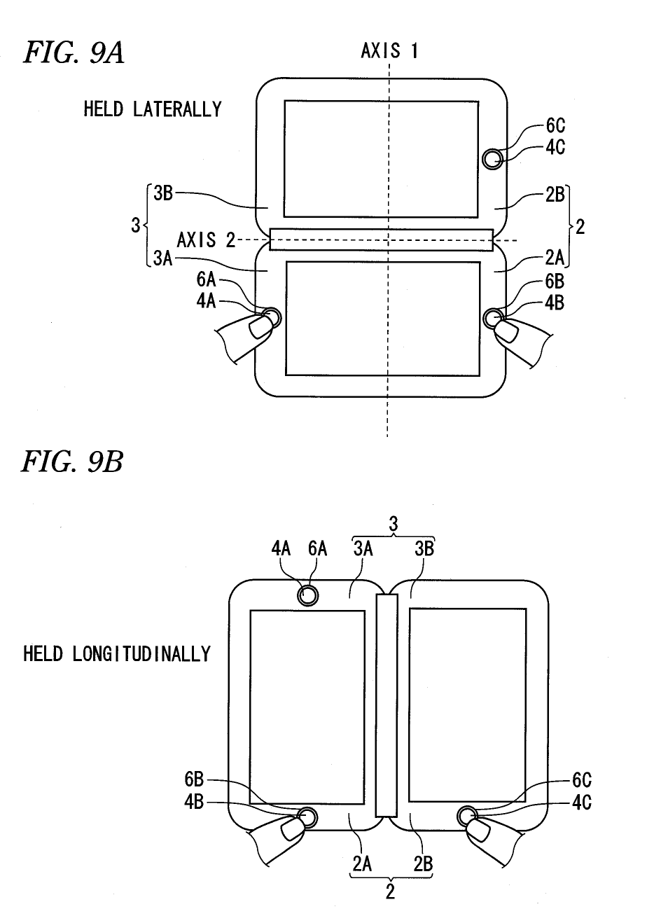

While the embodiment where the number of housings is one has been described above, the present invention may be applied to a case where the apparatus has pivotable housings 3A and 3B having displays 2A and 2B, respectively (see FIGS. 8 and 9A, 9B).

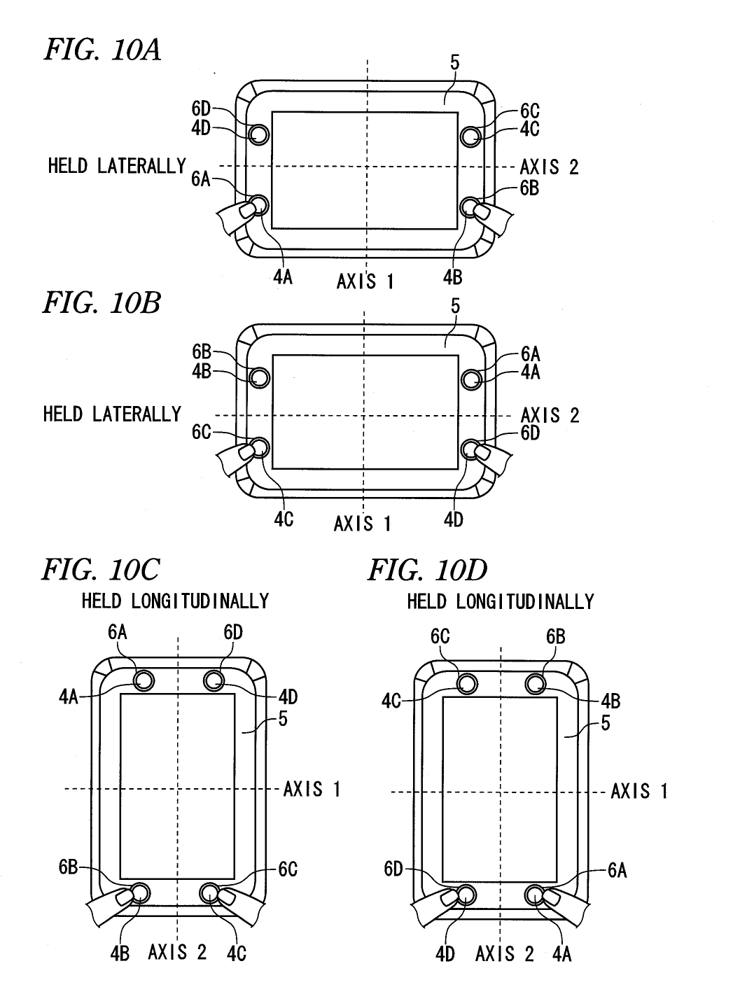

Moreover, while the embodiment where the number of buttons is three has been described above, a second embodiment where the number of buttons is four will be described with reference to FIGS. 10 to 12. As for components similar to those in the first embodiment where the number of buttons is three, regarding them as similar to those of the first embodiment, description and illustration thereof are partly omitted, and the same reference numerals are given thereto for explanation.

Moreover, as to the structure, although there is a difference in that the number of buttons is four, except for this, the structure is basically similar to that in the first embodiment where the number of buttons is three (FIG. 3). Therefore, description is omitted.

FIGS. 10A to 10D are views for explaining the holding condition of the information processing apparatus 1 in the second embodiment in which the number of buttons is four. FIGS. 10A and 10B show cases where the information processing apparatus 1 is held laterally, and between these figures, the information processing apparatus 1 is held in vertically opposite orientations. FIGS. 10C and 10D show cases where the information processing apparatus 1 is held longitudinally, and between these figures, the information processing apparatus 1 is held in vertically opposite orientations.

The buttons 4A and 4D are situated in positions symmetrical to the buttons 4B and 4C with respect to the axis 1, respectively. The buttons 4D and 4C are situated in positions symmetrical to the buttons 4A and 4B with respect to the axis 2, respectively.

The LEDs 6A, 6B, 6C and 6D are circumferentially provided around the buttons 4A, 4B, 4C and 4D, respectively.

As shown in FIGS. 10A to 10D, in the second embodiment, the image is displayed so that the lowermost side thereof is situated lowest with respect to the ground irrespective of the orientation of the information processing apparatus 1.

The functions assigned to the buttons 4A, 4B, 4C and 4D in a lateral holding case (1) (FIG. 10A) are the same as those assigned to the buttons 4C, 4D, 4A and 4B in a lateral holding case (2) (FIG. 10B), respectively. The functions assigned to the buttons 4A, 4B, 4C and 4D in the lateral holding case (1) (FIG. 10A) are the same as those assigned to the buttons 4B, 4C, 4D and 4A in a longitudinal holding case (1) (FIG. 10C), respectively, and are the same as those assigned to the buttons 4D, 4A, 4B and 4C in a longitudinal holding case (2) (FIG. 10D), respectively.

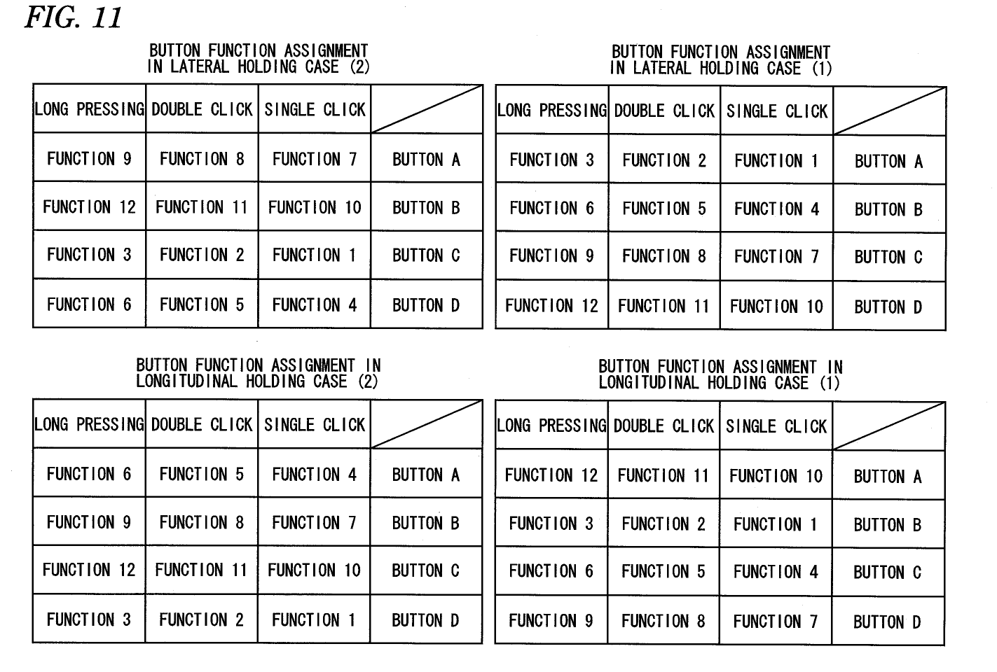

FIG. 11 shows an example of the button function assignment table 34A in the second embodiment where the number of buttons is four. In the example of FIG. 11, a plurality of functions assigned to the buttons A, B, C and D are defined for the four kinds of holding conditions in the lateral holding cases (1) and (2) and in the longitudinal holding cases (1) and (2). The user can perform three kinds of operations, a single click, a double click and a long pressing on the buttons, and a different function is assigned to each.

Further, for all the functions corresponding to these three kinds of operations, the assignment is changed according to the holding condition as described above and as shown in FIG. 11.

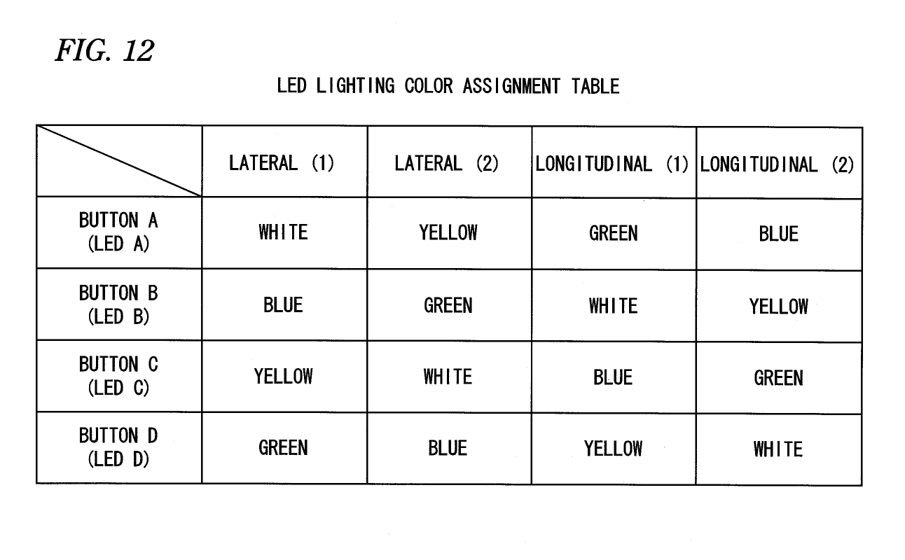

FIG. 12 is a view showing an example of the LED lighting color assignment table 34B. As shown in FIG. 12, in the LED lighting color assignment table 34B, the lighting colors assigned to the LED A, the LED B, the LED C and the LED D in the lateral holding case (1) are the same as those assigned to the LED C, the LED D, the LED A and the LED B in the lateral holding case (2), respectively. Likewise, the lighting colors assigned to the LED A, the LED B, the LED C and the LED D in the lateral holding case (1) are the same as those assigned to the LED B, the LED C, the LED D and the LED A in the longitudinal holding case (1) and those assigned to the LED D, the LED A, the LED B and the LED C in the longitudinal holding case (2), respectively.

The information processing apparatus 1 in the second embodiment where the number of buttons is four has been described above, and the advantages of the first embodiment where the number of buttons is three are all obtained also in the second embodiment.

Further, in the second embodiment where the number of buttons is four, no matter in which of the four orientations the user uses the apparatus, the user's operational feeling is similar since the image display and the button operations are changed accordingly, so that convenience improves.

While certain embodiments have been described, these embodiments have been presented by way of example only, and are not intended to limit the scope of the invention. Indeed, the novel apparatus described herein may be embodied in a variety of other forms; furthermore, various omissions, substitutions and changes in the form of the apparatus, described herein may be made without departing from the sprit of the invention. The accompanying claims and their equivalents are intended to cover such forms or modifications as would fall within the scope and sprit of the invention.

What is claimed is:

1. An information processing apparatus comprising:
a display configured to display an image in a first orientation or in a second orientation;
a first button and a second button substantially symmetric with respect to a first axis passing through a center of the display;
a third button substantially symmetric to the second button with respect to a second axis intersecting the first axis at a substantially right angle in the center of the display; and
a controller configured to assign a first function and a second function to the first button and the second button, respectively, when the display displays the image in the first orientation, and to assign the first function and the second function to the second button and the third button, respectively, when the display module displays the image in the second orientation.

2. The apparatus of claim 1, wherein the controller is configured to assign a third function to the third button when the display module displays the image in the first orientation, and to assign the third function to the first button when the display module displays the image in the second orientation.

3. The apparatus of claim 1, further comprising:
a fourth button substantially symmetric to the first button with respect to the second axis and substantially symmetric to the third button with respect to the first axis,
wherein the controller is configured to assign a third function and a fourth function to the third button and the fourth button, respectively, when the display displays the image in the first orientation, and to assign the fourth function and the third function to the first button and the fourth button, respectively, when the display displays the image in the second orientation.

4. The apparatus of claim 1, comprising:
a first indicator, a second indicator, and a third indicator, corresponding to the first button, the second button, and the third button, respectively,
wherein the controller is configured to assign the first indicator and the second indicator to a first indication rule when the display module displays the image in the first orientation and to assign the second indicator and the third indicator to the first indication rule when the display module displays the image in the second orientation are the same.

5. The apparatus of claim 1, further comprising:
a setting module configured to set the first function and the second function.

6. The apparatus of claim 2, further comprising:
a setting module configured to set the first function, the second function, and the third function.
